(19) United States
(12) Patent Application Publication
(10) Pub. No.: US 2026/0026314 A1
(43) Pub. Date: Jan. 22, 2026

(54) GALVANIC EFFECT MONITOR TEST STRUCTURE FOR IC PACKAGE INTERPOSER

(71) Applicant: Taiwan Semiconductor Manufacturing Co., Ltd., Hsinchu (TW)

(72) Inventors: Chi-Hui LAI, Hsinchu (TW); Ming Jun LI, Hsinchu (TW); Yang-Che CHEN, Hsinchu (TW); Hsiang-Tai LU, Hsinchu (TW); Wei-Ray LIN, Hsinchu (TW)

(21) Appl. No.: 18/776,118

(22) Filed: Jul. 17, 2024

(51) Int. Cl. H01L 21/66; G01N 17/02; H01L 21/48; H01L 23/00; H01L 23/14; H01L 23/498; H01L 23/538

(52) U.S. Cl. CPC H01L 22/32; G01N 17/02; H01L 21/4857; H01L 21/486; H01L 22/22; H01L 23/147; H01L 23/49816; H01L 23/49822; H01L 23/49833; H01L 23/49838; H01L 23/49866; H01L 23/49894; H01L 23/5385; H01L 23/5386; H01L 24/13; H01L 24/16; H01L 2224/13147; H01L 2224/16227; H01L 2224/16237; H01L 2924/365; H01L 2924/37001; H01L 2924/3841

(57) ABSTRACT

An integrated circuit package includes a substrate, a semiconductor interposer on the substrate, and a first integrated circuit chip on the interposer. The interposer includes a galvanic effect test structure including a test contact pad and a detection contact pad. The interposer includes a plurality of primary contact pads electrically coupled to the first integrated circuit chip. The galvanic effect structure can be utilized to test the interposer for galvanic corrosion prior to assembling the interposer into the integrated circuit package.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

With this scaling down of integrated circuit features, various efforts have also been made to address issues associated with packaging of integrated circuits. In some cases, an integrated circuit package includes a substrate, one or more integrated circuit chips, and an interposer between the substrate and the integrated circuit chips. However, there are many difficulties associated with such packaging that can result in scrapped wafers or other drawbacks.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a simplified illustration of components of an integrated circuit package prior to assembly, in accordance with some embodiments.

FIG. 1B is a simplified illustration of the components of the integrated circuit package of FIG. 1A after assembly, in accordance with some embodiments.

FIG. 2A is a cross-sectional view of an interposer of integrated circuit package including a galvanic effect test structure, in accordance with some embodiments.

FIG. 2B is a top view of the interposer of FIG. 2A, in accordance with some embodiments.

FIG. 3A is a cross-sectional view of an interposer of integrated circuit package including a galvanic effect test structure, in accordance with some embodiments.

FIG. 3B is a top view of the interposer of FIG. 3A, in accordance with some embodiments.

FIGS. 4A-4I are cross-sectional views of an integrated circuit package interposer at various stages of processing, in accordance with some embodiments.

FIG. 5 is an enlarged cross-sectional view of a portion of an interposer including galvanic corrosion, in accordance with some embodiments.

FIG. 6 is a cross-sectional view of an assembled integrated circuit package, in accordance with some embodiments.

FIG. 7 is a block diagram of an interposer testing and assembly system, in accordance with some embodiments.

FIG. 8 is a flow diagram of a method, in accordance with some embodiments.

FIG. 9 is a flow diagram of a method, in accordance with some embodiments.

FIG. 10 is a table illustrating comparative nobility of metals, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

Embodiments of the present disclosure provide an interposer for an integrated circuit package with a galvanic effect test structure. The integrated circuit package includes one or more integrated circuit chips positioned on top of the interposer. The interposer, in turn, is positioned on a substrate. The interposer includes electrical connectors that electrically coupled the one or more integrated circuit chips two electrical connectors on the substrate. Prior to mounting the one or more integrated circuit chips onto the interposer, the interposer undergoes a galvanic effect test utilizing the galvanic effect test structure of the interposer. The galvanic effect test determines whether or not there are defects in the interposer that result in the presence of a galvanic effect. If the testing of the galvanic effect test structure does not indicate the presence of a galvanic effect, then the interposer can be utilized in the integrated circuit package. The one or more integrated circuit chips can be mounted to the interposer and the interposer can be mounted to the substrate.

Embodiments of the present disclosure provide various benefits to integrated circuit packages and integrated circuit packaging techniques. The dedicated galvanic effect test structure enables detection of a galvanic effect on the interposer prior to coupling the one or more chips to the interposer. This avoids the situation in which the galvanic effect is not detected until after the one or more chips are mounted to the interposer, resulting in scrapping of the integrated circuit package and waste of the one or more chips. Instead, if the galvanic effect test structure indicates that the interposer is defective, only the relatively inexpensive interposer is scrapped with no loss of associated integrated circuit chips. This results in higher functioning integrated circuit packages, fewer scrapped wafers, and overall higher yields.

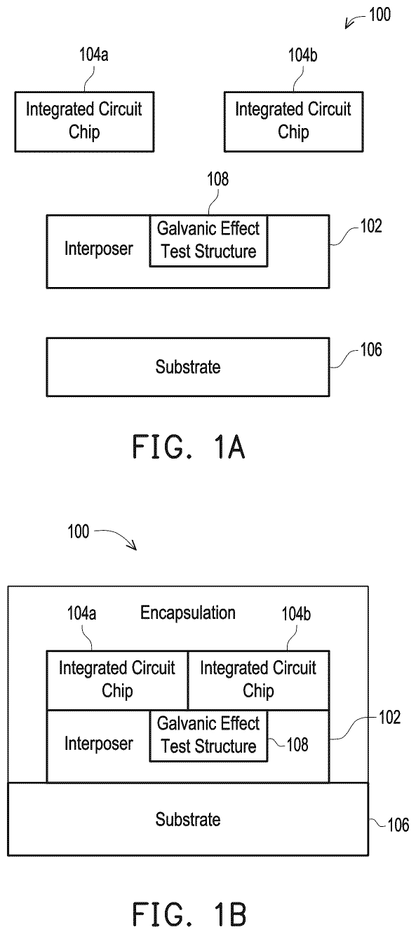

FIG. 1A is a simplified illustration of components of an integrated circuit package 100 prior to assembly, in accordance with some embodiments. The components of the integrated circuit package include an interposer 102, a first integrated circuit chip 104a, a second integrated circuit chip 104b, and a substrate 106. The interposer 102 includes a galvanic effect test structure 108. As will be set forth in more detail below, the galvanic effect test structure 108 helps to ensure that the components of the integrated circuit package 100 will function properly after assembly of the integrated circuit package.

As used herein, the suffixes “a” and “b” associated with the integrated circuit chips 104a and 104b may be omitted when reference is not made with particularity to either the integrated circuit chip 104a or the integrated circuit chip 104b. Accordingly, the integrated circuit chips 104a and 104b may be referred to generically with the reference number 104 without a suffix in the following description.

Though not shown in FIG. 1A, each of the components of the integrated circuit package 100 can include a plurality of interconnect structures that enable the passing of electrical signals to or from each of the components of the integrated circuit package 100. For example, each of the components of the integrated circuit package 100 can include one or more types of surface level interconnection structures such as contact pads, solder bumps, solder balls, redistribution layers, or other types of interconnect structures that enable signals to be passed to and from the various components of the integrated circuit package 100.

Upon assembly, the integrated circuit chips 104 will be mounted to the interposer 102. The interposer 102 will be mounted to the substrate 106. The integrated circuit chips 104 each include one or more surface level electrical interconnection structures on the bottoms of the integrated circuit chips 104 for electrical connection to corresponding surface level electrical interconnection structures on the top of the interposer 102. The interposer 102 includes surface level electrical interconnection structures on the bottom of the interposer 102 for electrical connection to corresponding surface level electrical interconnection structures on top of the substrate 106. The substrate 106 also includes surface level interconnection structures on the bottom of the substrate 106.

After assembly of the integrated circuit package 100, the integrated circuit package 100 can be mounted on a circuit board of an electronic device. The surface level interconnection structures on the bottom of the substrate 106 can be coupled to corresponding structures on the circuit board. Signals can be passed from the circuit board through the substrate 106, through the interposer 102, to the integrated circuit chips 104. Similarly, signals can be passed from the integrated circuit chips 104 through the interposer 102, through the substrate 106, to the circuit board. Signals can also be passed between the chips 104 via the interposer 102.

In some embodiments, the integrated circuit chips 104 each correspond to an integrated circuit die including a semiconductor material. Each integrated circuit chip 104 can include a plurality of transistors implemented in accordance with a semiconductor substrate. Each integrated circuit chip 104 can include conductive vias, metal lines, and other internal interconnect structures to form the circuit structures of the integrated circuit chip 104.

In some embodiments, the integrated circuit chips 104a and 104b are each diced from a system on chip (SoC) integrated circuit die. In some embodiments, the integrated circuit chips 104a and 104b may be termed chiplets. In some embodiments, the integrated circuit chips 104a and 104b are diced from separate wafers. In some embodiments, the integrated circuit chips 104a and 104b are each individual SoCs. Although FIG. 1A illustrates two integrated circuit chips 104a and 104b, in practice, there may be only a single integrated circuit chip or more than two integrated circuit chips 104.

It is possible that a galvanic effect can be present at the interposer 102 due to galvanic corrosion. Galvanic corrosion is an electrochemical process in which one metal corrodes preferentially when it is in electrical contact with another. In some cases, it is possible that such galvanic corrosion may occur at the upper surface of the interposer 102.

In some embodiments, the interposer 102 can include aluminum contact pads. A copper material may be positioned on the aluminum contact pads. A solder micro-bump may then be formed on top of the copper. In such a circumstance, it is possible that copper dendrite can be formed at the micro-bump the copper dendrite may contact the aluminum contact pad. This can result in chain leakages in the assembled package. More particularly, in some embodiments the interposer 102 may include aluminum contact pads of a primary test structure for performing primary test on the interposer. The primary test structure may correspond to a pretty good die (PGD) test structure for performing a PGD test on the interposer. The aforementioned copper dendrite may spill toward the aluminum test pads, resulting in the chain leakages. In some embodiments, the primary test structure is a wafer acceptance test (WAT) structure. In some embodiments, the WAT test uses a standard fabrication facility test tool with fixed probe tip/test channel. In some embodiments, the PGD test is more flexible on channel count with customized probe card that forces a voltage and reads either a voltage or a current.

In some possible solutions, the chain leakages may only be detected after assembly of the integrated circuit package. In other words, in some possible solutions the chain leakages may only be detected after the integrated circuit chips 104 have been mounted on the interposer 102. If the chain leakages resulting from the galvanic effect are detected after assembly of the package, that it is possible that the package will need to be scrapped. While the interposer itself may be relatively less expensive to produce, the integrated circuit chips 104 may be considerably more expensive to produce. Accordingly, detecting the galvanic effect after package assembly may result in scrapping of the integrated circuit chips 104 along with the package 100.

Embodiments of the present disclosure provide a solution that detects the galvanic effect in the interposer 102 prior to assembly. More particularly, the interposer 102 includes a galvanic effect test structure 108. The galvanic effect test structure 108 includes a detection contact pad and a test contact pad. At the stage of processing at which the galvanic effect test structure is utilized, the detection pad may be free of other structures on the surface, whereas a metal column or other metal structure and a solder micro-bump are positioned over the test contact pad.

In some embodiments, the detection contact pad is coupled to a ground plane that is buried within the interposer. The detection contact pad can be coupled to the ground plane via one or more conductive vias and metal lines. The test contact pad can be coupled to one or more other circuit structures embedded within the interposer and which, after assembly, will connect to one or more other components of the package. Accordingly, the galvanic effect test structure can include a buried ground plane and various conductive vias and metal interconnect lines.

In some embodiments, a test circuit is coupled to the interposer to perform a galvanic effect test in order to detect galvanic corrosion or galvanic effect at the interposer. The test circuit can include one or more probes or leads. A first probe may contact the solder micro-bump positioned on the test contact pad of the galvanic effect test structure. A second probe may directly contact the detection pad of the galvanic effect test structure. The test circuit can apply one or more test signals to the test contact pad and a measure one or more response signals at the detection contact pad. The one or more response signals can include a voltage, current, a charge, or other electrical characteristics that can indicate the presence or absence of a galvanic effect.

In some embodiments, the interposer includes a primary test structure. The primary test structure can include a primary test contact pad and a primary detection contact pad. The detection contact pad may be coupled to the buried ground plane. In cases in which a primary test contact pad is present, the galvanic effect test can be performed concurrently or consecutively with the primary test by saying test circuit. Accordingly, in some embodiments the galvanic effect test can be conveniently performed in conjunction with other tests that will also be performed by the same test equipment.

In some embodiments, if the galvanic effect test indicates galvanic corrosion or the presence of a galvanic effect, then the interposer 102 can be scrapped prior to assembly of the package 100. If the galvanic effect test indicates that there is no galvanic corrosion or galvanic effect, then assembly of the package 100 can continue, including mounting of the chips 104 on the interposer 102.

In some embodiments, the interposer 102 is a semiconductor interposer. The semiconductor interposer can include a semiconductor substrate. Various dielectric layers, metal lines, conductive vias, contact pads, and solder bumps can be formed above the semiconductor substrate as described previously. Conductive structures such as through-silicon vias (TSVs) can be formed through the semiconductor substrate to provide electrical connection between the various conductive structures above the semiconductor substrate and the substrate 106 that will be coupled to the bottom of the interposer 102. While the term TSV may refer to a “through-silicon via”, in practice, the TSV may also refer to a “through-semiconductor via” for cases in which the interposer includes semiconductor chip or semiconductor substrate other than silicon.

In some embodiments, the interposer 102 is an integrated circuit chip including top and bottom interconnection structures and TSVs. The interposer 102 can include transistors and other circuitry formed in conjunction with the semiconductor substrate. In some embodiments, the interposer includes an integrated circuit chip or semiconductor die embedded in a dielectric structure. The dielectric structure can include a molding compound or other types of structures. Conductive vias can be formed in the dielectric structure of areas lateral to the integrated circuit chip of the interposer 102. The tops and bottom of the dielectric structure can include redistribution lines made of a redistribution metal layer.

The substrate 106 can include a package substrate such as a PCB substrate, an organic substrate, or other types of substrates. Surface level interconnection structures at the top of the substrate 106 can be coupled to the bottom of the interposer 102 via C4 copper bumps or other types of conductive structures. The substrate 106 can include package traces or other internal interconnect structures that provide electrical connection between surface level connection structures at the top of the substrate 106 and surface level connection structures at the bottom of the substrate 106. Package balls can be coupled to the bottom of the substrate 106 to enable electrical connection to a circuit board on which the package 100 can be mounted. Various other conductive structures can be utilized without departing from the scope of the present disclosure.

FIG. 1B is a simplified illustration of the integrated circuit package 100 after assembly. In particular, the integrated circuit chips 104a and 104b have been coupled to the top of the interposer 102. The interposer 102 has been coupled to the top of the substrate 106. An encapsulation 110 has been formed on the substrate surrounding the interposer 102 and the integrated circuit chips 104a and 104b. The encapsulation 110 can include a molding compound, a dielectric housing, or other structures to protect the integrated circuit chips 104a and 104b and the interposer 102. Assembly of the package 100 is performed after the interposer 102 has been tested for galvanic effect via the galvanic effect test structure 108, as described previously.

The integrated circuit package 100 can correspond to an interposer-based package, a local silicon interconnect (LSI) based package, an integrated fan out (InFO) based package, a chip on the wafer on substrate (CoWoS) based package, a system on integrated chip (SoIC) based package, a wafer on wafer (WoW) based package, or other types of packages.

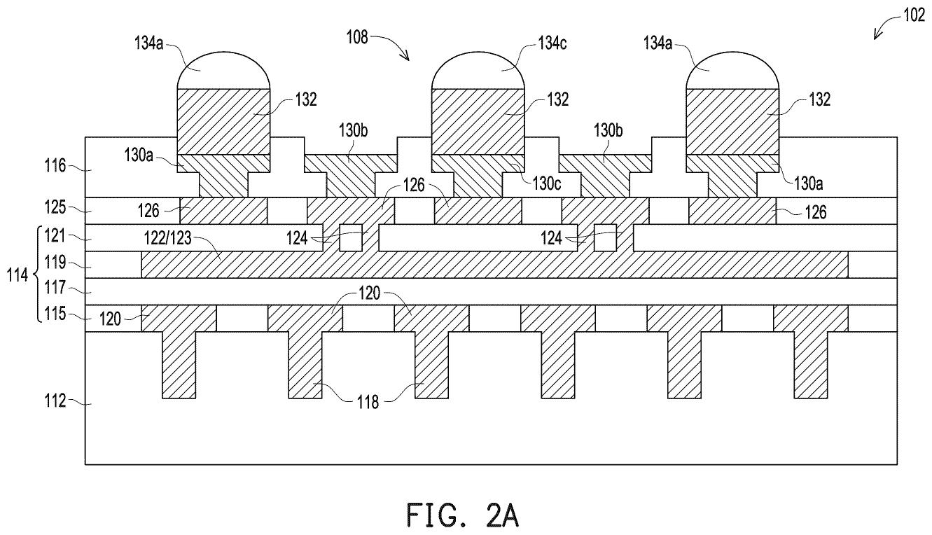

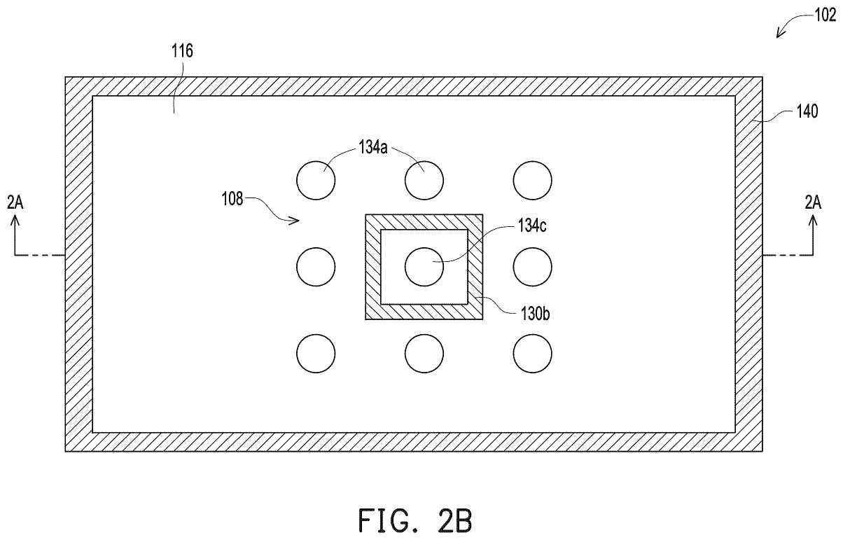

FIG. 2A is a cross-sectional view of an interposer 102 including a galvanic effect test structure 108, in accordance with some embodiments. The interposer 102 of FIG. 2A is one example of an interposer 102 of FIGS. 1A and 1B. The interposer 102 may correspond to a semiconductor integrated circuit chip or semiconductor die. Alternatively, though not shown, the portion of the interposer 102 shown in FIG. 2A may correspond to a semiconductor die that is embedded in an additional interposer structure not illustrated in FIG. 2A.

The interposer 102 includes a semiconductor substrate 112. The interposer 102 includes a dielectric stack 114 on the semiconductor substrate 112. The interposer 102 includes a passivation layer 116 on top of the dielectric stack 114.

The semiconductor substrate 112 can include silicon, silicon germanium, or other suitable semiconductor materials. Though not shown in FIG. 2A, in some embodiments transistors can be formed in conjunction with the semiconductor substrate 112. The substrate 112 includes TSVs 118 extending from a top of the semiconductor substrate 112 downward into though not shown in FIG. 2A, the TSVs can extend all the way to the bottom of the semiconductor substrate 112 to facilitate connection with the substrate 106, or with other components depending on the configuration of the package 100 in which the interposer 102 is to be implemented.

The TSVs 118 correspond to conductive vias. The TSVs 118 can include a metal material. In an exemplary embodiment, the TSVs include copper. Alternatively, the TSVs can include tungsten, aluminum, titanium, titanium nitride, tantalum, tantalum nitride, or other suitable conductive materials.

In some embodiments the dielectric stack 114 corresponds to a plurality of interlevel dielectric layers formed above the semiconductor substrate 112. The dielectric stack 114 includes a first interlevel dielectric layer 115. The first interlevel dielectric layer 115 can include one or more of SiO, SiN, SiON, SiOCN, SiOC, SiCN, AlO, or other suitable dielectric materials.

A plurality of metal lines 120 are formed on the top surface of the semiconductor substrate 112. The metal lines 120 may each connect to a respective TSV 118. Though not shown, some metal lines 120 may connect to multiple TSVs. Some metal lines 120 may not directly contact any TSV 118. In an exemplary embodiment, the metal lines 120 include copper. However, the metal lines 120 can include tungsten, aluminum, titanium, titanium nitride, tantalum, tantalum nitride, or other suitable conductive materials. The metal lines 120 may correspond to a first metal interconnection layer, sometimes termed metal 1. The metal lines 120 are covered by the interlevel dielectric layer 115.

The dielectric stack 114 includes a second interlevel dielectric layer 117 on the first interlevel dielectric layer 115. The second interlevel dielectric layer 117 can include one or more of SiO, SiN, SiON, SiOCN, SiOC, SiCN, AlO, or other suitable dielectric materials. Though not shown in FIG. 2A, conductive vias or plugs may be formed in the interlevel dielectric layer 117 and in contact with the top surfaces of the metal lines 120.

The dielectric stack 114 includes a third interlevel dielectric layer 119. The third interlevel dielectric layer 119 can include one or more of SiO, SiN, SiON, SiOCN, SiOC, SiCN, AlO, or other suitable dielectric materials.

A plurality of metal lines 122 are formed on the top surface of the interlevel dielectric layer 117. The metal lines 122 may each connect to the top surface of a respective conductive via formed in the first interlevel dielectric layer 117. In an exemplary embodiment, the metal lines 122 include copper. However, the metal lines 122 can include tungsten, aluminum, titanium, titanium nitride, tantalum, tantalum nitride, or other suitable conductive materials. The metal lines 122 may correspond to a second metal interconnection layer, sometimes termed metal 2. The metal lines 122 are covered by the interlevel dielectric layer 119.

The dielectric stack 114 includes a fourth interlevel dielectric layer 121 on the third interlevel dielectric layer 119. The fourth interlevel dielectric layer 121 can include one or more of SiO, SiN, SiON, SiOCN, SiOC, SiCN, AlO, or other suitable dielectric materials. Conductive vias 124 have been formed in the interlevel dielectric layer 121 in contact with the top surfaces of some of the metal lines 122. The conductive vias 124 can include copper, tungsten, aluminum, titanium, titanium nitride, tantalum, tantalum nitride, or other suitable conductive materials.

FIG. 2A illustrates a ground plane 123 formed from a same material and in a same deposition step as the metal lines 122. The ground plane 123 is part of the galvanic effect test structure 108. The ground plane 123 corresponds to a large metal plane that is embedded within the interposer 102.

The dielectric stack 114 includes a fifth interlevel dielectric layer 125 on the fourth interlevel dielectric layer 121. The fifth interlevel dielectric layer 125 can include one or more of SiO, SiN, SiON, SiOCN, SiOC, SiCN, AlO, or other suitable dielectric materials.

A plurality of metal lines 126 are formed on the top surface of the interlevel dielectric layer 121. The metal lines 126 may each connect to the top surface of a respective conductive via 124 formed in the fourth interlevel dielectric layer 121. In an exemplary embodiment, the metal lines 126 include copper. However, the metal lines 126 can include tungsten, aluminum, titanium, titanium nitride, tantalum, tantalum nitride, or other suitable conductive materials. The metal lines 126 may correspond to a third metal interconnection layer, sometimes termed metal 3. The metal lines 126 are covered by the interlevel dielectric layer 125.

The passivation layer 116 is formed on the interlevel dielectric layer 125. The passivation layer 116 can include SiN, SiON, SiOCN, SiOC, SiCN, or other suitable dielectric layers. While FIG. 2A illustrates the passivation layer 116 as a single passivation layer, in practice, the passivation layer 116 can include multiple layers.

The passivation layer 116 includes openings that expose the metal lines 126 of the third interlevel dielectric layer 125. The contact pads 130 are formed in the openings on exposed portions of the metal lines 126. The contact pads 130 can be formed of a metal material. In some embodiments contact pads 130 are formed of a different than the metal lines 126. In an example in which the metal lines 126 are copper, the contact pads 130 may be aluminum. Other metals can be utilized for the contact pads 130 without departing from the scope of the present disclosure.

In FIG. 2A, there are contact pads 130a, contact pads 130b, and a contact pad 130c. The contact pads 130a correspond to primary contact pads associated with standard function of the interposer 102 and are configured to be electrically coupled to an integrated circuit chip 104. A metal pillar 132 is positioned on top of and in contact with each of the contact pads 130a. The metal pillar 132 includes a metal material different than the material of the contact pads 130a. In an example in which the contact pads 130 are aluminum, the metal pillars 132 can include copper. Other materials can be utilized for the metal pillars 132 without departing from the scope of the present disclosure. Solder micro-bumps 134a are formed on the metal pillars 132. As will be set forth in more detail below, the solder micro-bumps 134a and the metal pillars 132 are utilized to provide electrical interconnection between the interposer 102 and the integrated circuit chips 104.

The contact pads 130b are distinct from the contact pads 130a in that the metal pillars 132 are not formed on the contact pads 130b. Accordingly, at the stage of processing shown in FIG. 2A, the contact pads 130b are naked or exposed, while the contact pads 130a are covered by the metal pillars 132 and micro-bumps 134. A central contact pad 130c is also covered by a metal pillar 132 and a micro-bump 134c.

In some embodiments, the contact pad 130c is a test contact pad of the galvanic effect test structure 108. In some embodiments, the contact pad 130b is a detection contact pad of the galvanic effect test structure 108. Accordingly, the contact pads 130b and one or more of the contact pads 130c and the accompanying metal pillar 132 and micro-bump 134c are part of the galvanic effect test structure 108. The ground plane 123 is also part of the galvanic effect test structure 108.

As can be seen in FIG. 2A, the detection contact pads 130b are directly electrically coupled to the ground plane 123 via one or more of the metal lines 126 and conductive vias 124. The test contact pad 130c is not directly electrically coupled to the ground plane 123. Instead, the detection contact pads 130c may be part of the standard electrical interconnection network of the interposer 102 that enables electrical signals to be passed between one or more components of the package 100 via the interposer 102, along with the contact pads 130a.

As described previously, it is possible that copper dendrite can be formed at the micro-bumps 134. The copper dendrite may spill or flow and contact an aluminum contact pad 130. This can result in chain leakages in the assembled package. More particularly, in some embodiments the interposer 102 may include aluminum contact pads for performing a primary test (such as a PGD test) on the interposer. The aforementioned copper dendrite may spill toward the aluminum primary test pads, resulting in the chain leakages.

Prior to assembly of the package 100, the galvanic effect test can be performed in conjunction with the galvanic effect test structure 108. In some embodiments, during the galvanic effect test, a test circuit is coupled to the interposer 102 to perform a galvanic effect test in order to detect galvanic corrosion or galvanic effect at the interposer. The test circuit can include one or more probes or leads. A first probe may contact the solder micro-bump 134c positioned on the test contact pads 130c of the galvanic effect test structure 108. A second probe may directly contact the exposed detection contact pad 130b of the galvanic effect test structure 108. The test circuit can apply one or more test signals to the test contact pad 130c and can measure one or more response signals at the detection contact pad 130b. The one or more response signals can include a voltage, current, a charge, or other electrical characteristics that can indicate the presence or absence of a galvanic effect. In some embodiments, the galvanic effect test includes applying a voltage and sensing a current. If there is no current, the there is no galvanic effect. If there is a current present, this represents a leakage current due to galvanic effect.

In some embodiments, the detection contact pad 130b includes a low noble metal surrounding the target test contact pad 130c. The low noble metal can help attract copper dendrite toward itself to detect a bridge resulting from galvanic corrosion. In some embodiments, the low noble metal is aluminum, as described previously. Other low noble metals can be utilized for the detection contact pad 130b without departing from the scope of the present disclosure. In some embodiments, a plurality of low noble detection contact pads 130b are placed within a minimum micro-bump pitch distance from the micro-bumps 134a. This can help increase the sensitivity of the galvanic effect test structure 108.

In some embodiments, the ground plane 123 has a surface area that is significantly larger than the surface area of the test contact pad 130c. In some embodiments, the ground plane 123 has an area that is more than 4000 times the area of the test contact pad 130c. Such a large difference in the area can significantly help the sensitivity of the galvanic effect test. This large difference in area can result in a large charge potential difference during the galvanic effect test, if galvanic corrosion is present.

FIG. 2B is a top view of the interposer 102 of FIG. 2A, in accordance with some embodiments. The cross-sectional view of FIG. 2A is taken along cut lines 2A in FIG. 2B. The top view of FIG. 2B illustrates that the exposed detection contact pad 134b has a rectangular shape that surrounds a central solder micro-bump 134c (and buried test contact pad 130c). An array of solder micro-bumps 134a (and buried contact pads 130a) surround the detection contact pad 130b. In some embodiments, the detection pad 134b is separated from the micro-bump 134 by a distance between 2 μm and 4 μm. FIG. 2B also illustrates a ground ring 140 around the periphery of the interposer 102. The ground ring 140 can include copper or another conductive material. Ground voltage can be applied to the ground ring 140. In some embodiments, the ground ring 140 is electrically coupled to the buried ground plane 123. Other arrangements of surface components of the galvanic effect test structure 108 can be utilized without departing from the scope of the present disclosure.

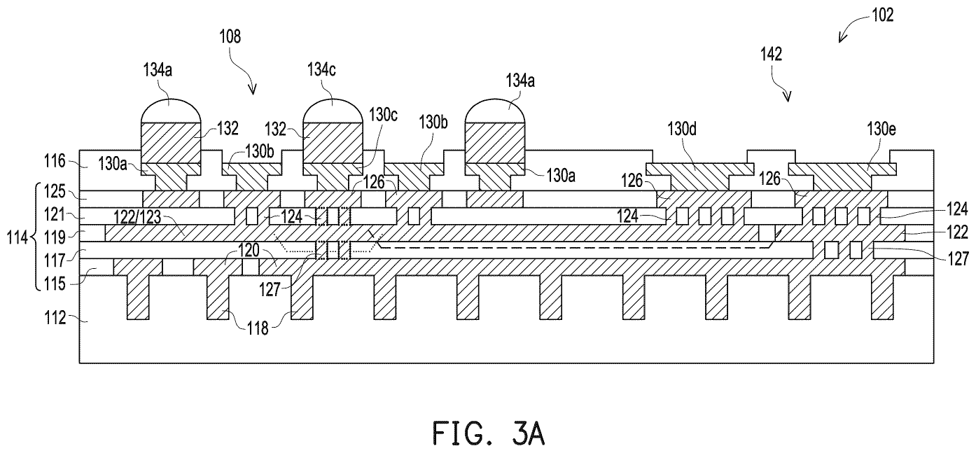

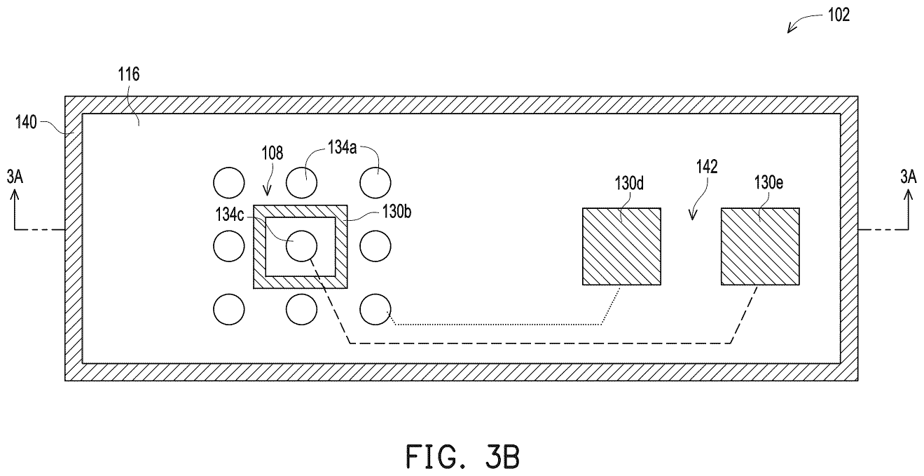

FIG. 3A is a cross-sectional view of an interposer 102, in accordance with some embodiments. The interposer 102 is one example of an interposer 102 of FIGS. 1A and 1B. The interposer 102 of FIG. 3A shares many of the same structures as the interposer 102 of FIG. 2A. The shared structures are labeled with the same reference numbers.

In some embodiments, the interposer 102 of FIG. 3A includes a primary test structure 142. The primary test structure 142 may correspond to a PGD test structure. As described previously, the primary test structure 142 is utilized to detect the quality and functionality of the interconnection structures of the interposer 102 prior to assembly of the package 100. Advantageously, the galvanic effect test structure 108 can be utilized in a same testing procedure to determine whether galvanic corrosion is present.

The primary test structure 142 includes a primary test contact pad 130e and a primary detection contact pad 130d. During the primary test, a first probe is connected to the primary test contact pad 130e and test signals are applied to the primary contact pad 130e via the first probe. During the primary test, second probe is connected to the primary detection contact pad 130d. One or more electrical signals are detected at the primary detection pad 130d to determine the quality of the interconnection structures of the interposer 102.

The primary test contact pad 130e is electrically connected to one or more metal line 120 in the first interlevel dielectric layer 115 via a metal line 126, conductive vias 124, a metal line 122, and conductive vias 127 formed in the first interlevel dielectric layer 115. The metal line 120 to which the test contact pad 130e is coupled may correspond to a ground plane. The primary detection contact pad 130d is connected to the ground plane 123 via a metal line 126 and conductive vias 124.

In some embodiments, the galvanic effect test contact pad 130c is coupled to the buried ground plane or metal line 120 by one or more conductive vias 124 and 127, bypassing the ground plane 123. Various other arrangements and configurations of the primary test structure 142 and the galvanic effect test structure 108 can be utilized without departing from the scope of the present disclosure.

FIG. 3B is a top view of the interposer 102 of FIG. 3A, in accordance with some embodiments. The cross-sectional view of FIG. 3A is taken along cut lines 3A from FIG. 3B. The top view of FIG. 3B illustrates the positions of the galvanic effect test structure 108 and the primary test structure 142. The ground ring 140 is present in FIG. 3B. Other arrangements and configurations of the primary test structure 142 and the galvanic effect test structure 108 can be utilized without departing from the scope of the present disclosure.

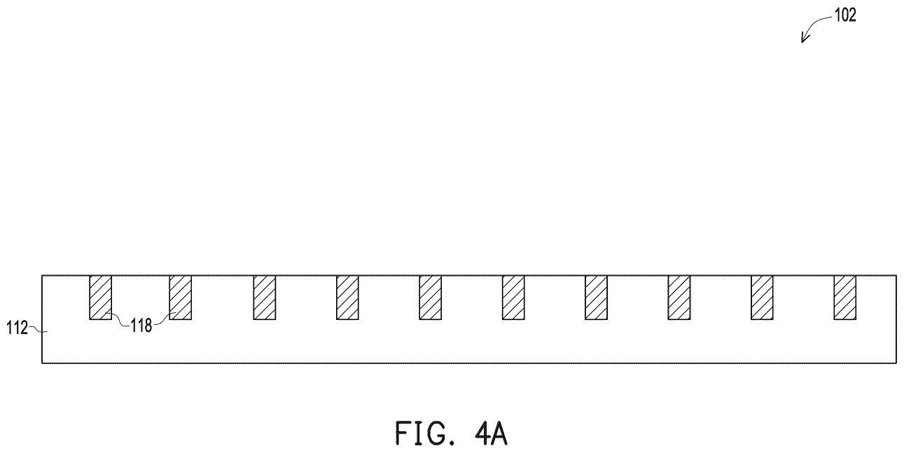

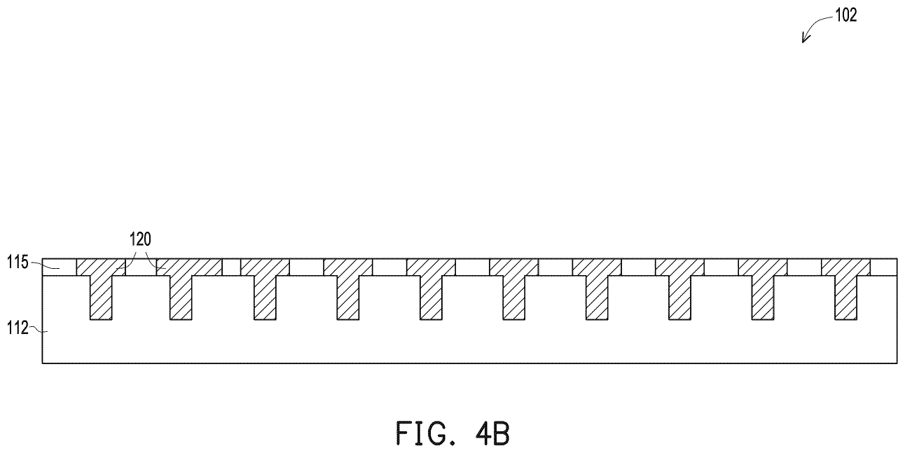

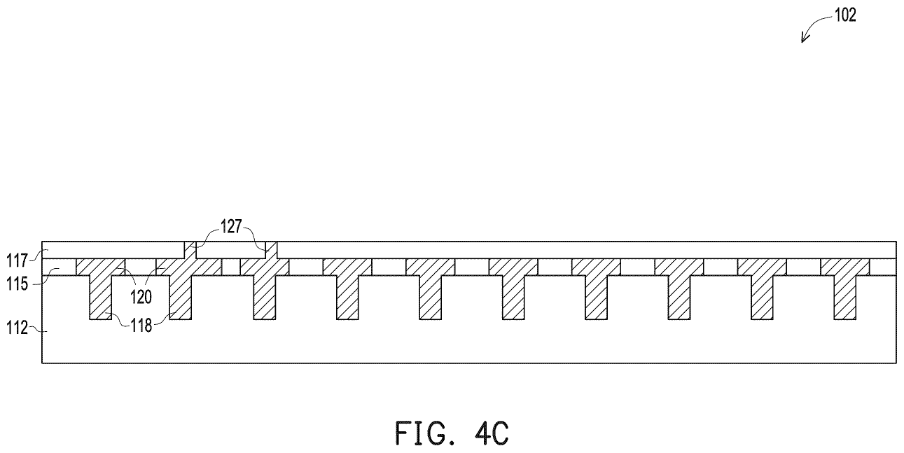

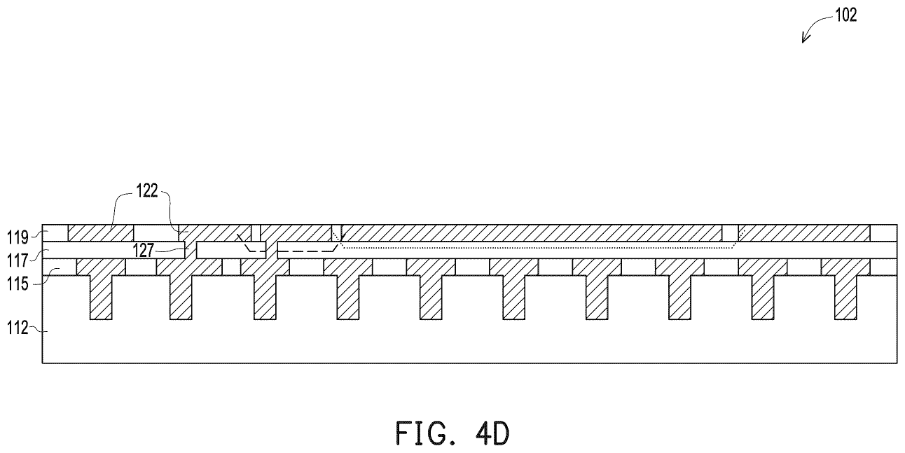

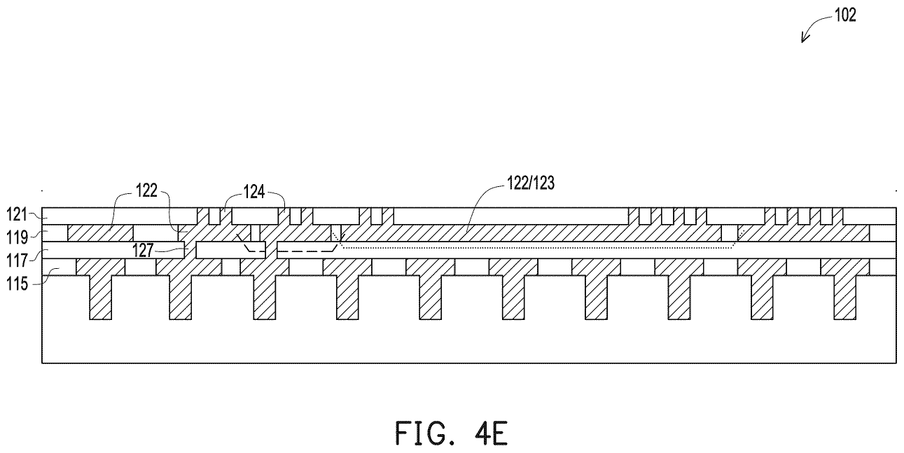

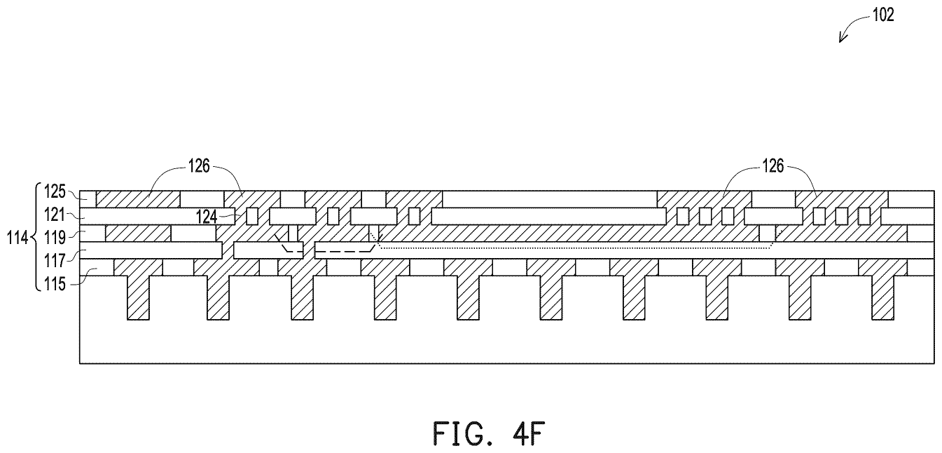

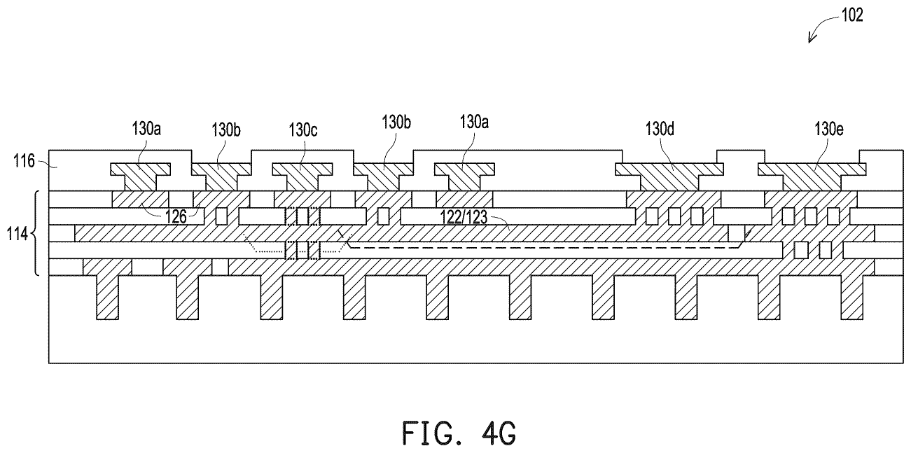

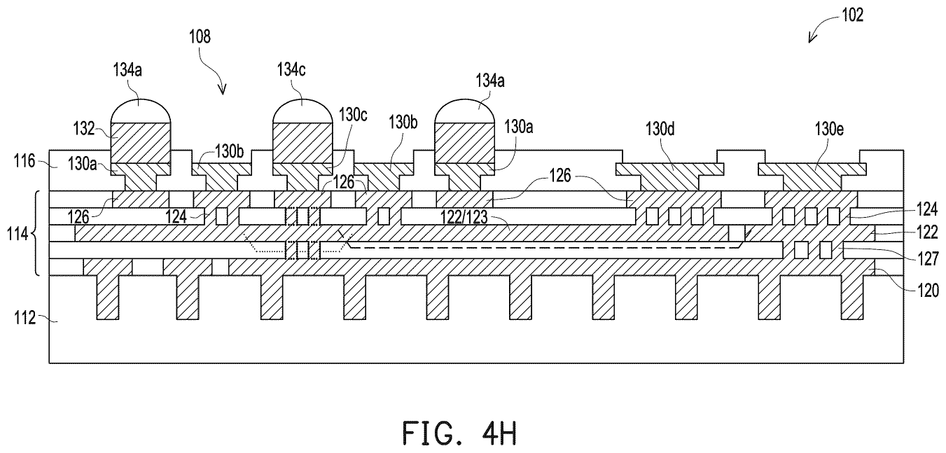

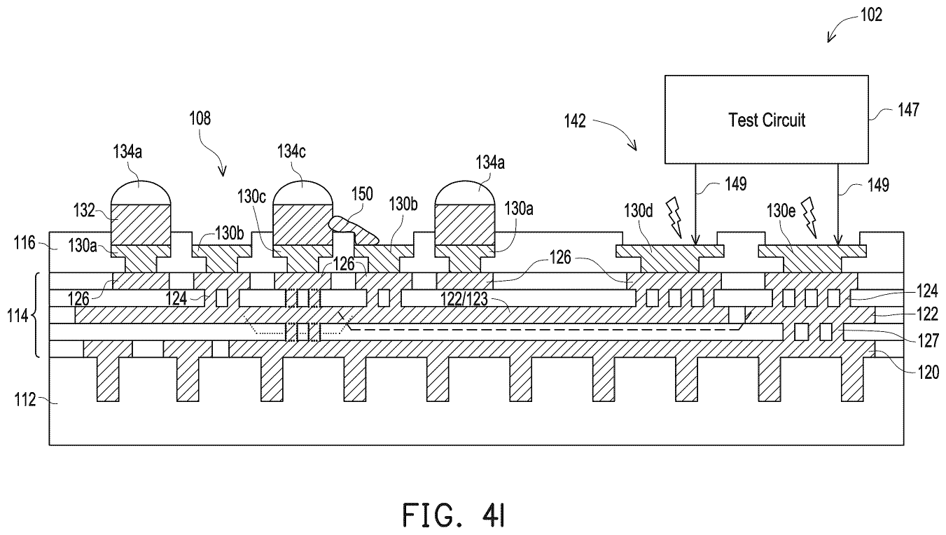

FIGS. 4A-4I are cross-sectional views of an interposer 102, at various stages of processing. FIGS. 4A-4I illustrate a process for forming the interposer 102 of FIGS. 3A and 3B, though the process can also be utilized to form the interposer 102 of FIGS. 2A and 2B.

In FIG. 4A, the interposer 102 includes the semiconductor substrate 112. The semiconductor substrate 112 can include silicon, silicon germanium, or other suitable semiconductor materials. In FIG. 4A, TSVs 118 have been formed in the semiconductor substrate extending from a top of the semiconductor substrate 112 downward into the semiconductor substrate 112. Though not shown in FIG. 2A, the TSVs 118 can extend all the way to the bottom of the semiconductor substrate 112 to facilitate connection with the substrate 106, or with other components depending on the configuration of the package 100 in which the interposer 102 is to be implemented. In an exemplary embodiment, the TSVs 118 include copper. Alternatively, the TSVs can include tungsten, aluminum, titanium, titanium nitride, tantalum, tantalum nitride, or other suitable conductive materials.

In FIG. 4B, first interlevel dielectric layer 115 has been formed on the semiconductor substrate 112 and on the TSVs 118. The first interlevel dielectric layer 115 can include one or more of SiO, SiN, SiON, SiOCN, SiOC, SiCN, AlO, or other suitable dielectric materials. The first interlevel dielectric layer 115 can be deposited via chemical vapor deposition (CVD), atomic layer deposition (ALD), physical vapor deposition (PVD), or other suitable deposition processes.

In FIG. 4B, the interlevel dielectric layer 115 has been patterned to expose the TSVs 118. A plurality of metal lines 120 have been formed on the top surface of the semiconductor substrate 112 in the openings in the interlevel dielectric layer 115. The metal lines 120 may each connect to a respective TSV 118. Though not shown, some metal lines 120 may connect to multiple TSVs. Some metal lines 120 may not directly contact any TSV 118. In an exemplary embodiment, the metal lines 120 include copper. However, the metal lines 120 can include tungsten, aluminum, titanium, titanium nitride, tantalum, tantalum nitride, or other suitable conductive materials. The metal lines 120 may correspond to a first metal interconnection layer, sometimes termed metal 1. The metal lines 120 are covered by the interlevel dielectric layer 115. The metal lines 120 can be deposited via PVD, ALD, CVD, or other suitable deposition processes.

In FIG. 4C, a second interlevel dielectric layer 117 has been formed on the first interlevel dielectric layer 115. The second interlevel dielectric layer 117 can include one or more of SiO, SiN, SiON, SiOCN, SiOC, SiCN, AlO, or other suitable dielectric materials. The interlevel dielectric layer 117 can be formed by CVD, ALD, PVD, or other suitable deposition processes.

In FIG. 4C, conductive vias 127 have been formed in the interlevel dielectric layer 117 and in contact with the top surfaces of the metal lines 120. The conductive vias 127 can be formed by patterning the interlevel dielectric layer 117 to form trenches exposing selected metal lines 120 and depositing a conductive material in the trenches. The conductive material can include copper, aluminum, tungsten, titanium, tantalum, or other suitable conductive materials. The conductive material can be deposited via PVD, ALD, CVD, or other suitable deposition processes.

In FIG. 4D, a third interlevel dielectric layer 119 has been formed on the interlevel dielectric layer 117. The third interlevel dielectric layer 119 can include one or more of SiO, SiN, SiON, SiOCN, SiOC, SiCN, AlO, or other suitable dielectric materials. The interlevel dielectric layer 119 can be formed by CVD, ALD, PVD, or other suitable deposition processes.

In FIG. 4D, a plurality of metal lines 122 have been formed on the top surface of the interlevel dielectric layer 117. The metal lines 122 may each connect to the top surface of a respective conductive via formed in the first interlevel dielectric layer 117. In an exemplary embodiment, the metal lines 122 include copper. However, the metal lines 122 can include tungsten, aluminum, titanium, titanium nitride, tantalum, tantalum nitride, or other suitable conductive materials. The metal lines 122 may correspond to a second metal interconnection layer, sometimes termed metal 2. The metal lines 122 can be formed by patterning the interlevel dielectric layer 121 to form trenches in the interlevel dielectric layer 121 and depositing the conductive material in the trenches. The conductive material can be deposited by PVD, ALD, CVD, or other suitable deposition processes.

In FIG. 4E, a fourth interlevel dielectric layer 121 has been formed on the third interlevel dielectric layer 119. The fourth interlevel dielectric layer 121 can include one or more of SiO, SiN, SiON, SIOCN, SiOC, SiCN, AlO, or other suitable dielectric materials. The interlevel dielectric layer 121 can be formed by CVD, ALD, PVD, or other suitable deposition processes.

In FIG. 4E, conductive vias 124 have been formed in the interlevel dielectric layer 121 in contact with the top surfaces of some of the metal lines 122. The conductive vias 124 can include copper, tungsten, aluminum, titanium, titanium nitride, tantalum, tantalum nitride, or other suitable conductive materials. The conductive vias 124 can be formed in a similar manner described in relation to the conductive vias 127. The ground plane 123 is formed from a same material and in a same deposition step as the metal lines 122. The ground plane 123 is part of the galvanic effect test structure 108. The ground plane 123 corresponds to a large metal plane that is grounded and that is embedded within the interposer 102.

In FIG. 4F, a fifth interlevel dielectric layer 125 has been deposited on the fourth interlevel dielectric layer 121. The fifth interlevel dielectric layer 125 can include one or more of SiO, SiN, SiON, SiOCN, SiOC, SiCN, AlO, or other suitable dielectric materials. The interlevel dielectric layer 125 can be deposited by CVD, ALD, PVD, or other suitable deposition processes.

In FIG. 4F, a plurality of metal lines 126 have been formed on the top surface of the interlevel dielectric layer 121. The metal lines 126 may each connect to the top surface of a respective conductive via 124 formed in the fourth interlevel dielectric layer 121. In an exemplary embodiment, the metal lines 126 include copper. However, the metal lines 126 can include tungsten, aluminum, titanium, titanium nitride, tantalum, tantalum nitride, or other suitable conductive materials. The metal lines 126 may correspond to a third metal interconnection layer, sometimes termed metal 3. The metal lines 126 can be formed in a manner similar to that described in relation to the metal lines 120.

In FIG. 4G, a passivation layer 116 has been formed on the interlevel dielectric layer 125. The passivation layer 116 can include SiN, SiON, SiOCN, SiOC, SiCN, or other suitable dielectric layers. While FIG. 4G illustrates the passivation layer 116 as a single passivation layer, in practice, the passivation layer 116 can include multiple layers. For example, a first passivation layer may be formed and patterned to expose the metal lines 126. The lower contact pads 130 may then be formed on the exposed metal lines 126.

The contact pads 130 can be formed of a metal material. In some embodiments contact pads 130 are formed of a different than the metal lines 126. For example, the contact pads 130 can be formed of a low noble metal. In an example in which the metal lines 126 are copper, the contact pads 130 may be aluminum. Other metals can be utilized for the contact pads 130 without departing from the scope of the present disclosure. The contact pads 130 can be formed via PVD, ALD, CVD, or other suitable deposition processes.

After formation of the contact pads 130, a second passivation layer may be formed on the first passivation layer and on the contact pads 130. The second passivation layer may then be patterned to expose the contact pads 130b of the galvanic effect test structure 108 and the contact pads 130d and 130e of the primary test structure 142, as shown in FIG. 4G.

In FIG. 4H, the metal pillars 132 have been formed on the contact pads 130a and on the test contact pad 130c of the galvanic effect test structure 108. The metal pillars 132 includes a metal material different than the material of the contact pads 130. In an example in which the contact pads 130 are aluminum, the metal pillars 132 can include copper. Other materials can be utilized for the metal pillars 132 without departing from the scope of the present disclosure. In FIG. 4H, solder micro-bumps 134 have been formed on the metal pillars 132.

In FIG. 4I, copper dendrite has been formed at the metal pillar 132 and solder micro-bumps 134c and have spilled are flowed onto the detection contact pad 130b. A galvanic effect test can detect the bridge formed by the copper dendrite 150. In some embodiments, the primary test at the primary contact pads 130d and 130e can detect the galvanic effect resulting from the copper dendrite.

FIG. 4I also illustrates a test circuit 147 performing a primary test at the primary test structure 142. In particular, a first lead 149 is coupled to the test contact pad 130 E. A second lead 149 is coupled to the detection contact pad 130d. A test signal is then applied to the test contact pad 130 E and a response signal is measured at the test contact pad 130d. The primary test can detect the quality of the interposer 102. In some embodiments, the primary test can also detect the presence of the copper dendrite 150 forming a bridge. Alternatively, the test circuit 147 can apply individual probes to the solder micro-bumps 130 4C and the galvanic effect detection electrode 130b.

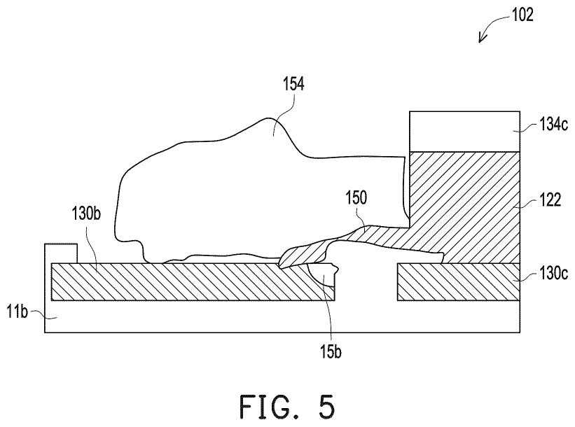

FIG. 5 is an enlarged cross-sectional view of a portion of the interposer 102, in accordance with some embodiments. In FIG. 5, a distilled water rinse has been performed on the interposer 102. Distilled water 154 is utilized to rinse the top of the interposer 102. The potential difference may be applied between the detection electrode 130b and the solder micro-bumps 130 4C. Copper dendrite 150 has formed and flowed onto the detection contact pad 130b. This results in corrosion 156 of the detection electrode 130b. The galvanic effect test, as described previously can detect this corrosion so that the interposer 102 can be scrapped prior to assembly of the package.

In some embodiments, the metal pillars 132 can be formed of a high noble metal such as gold, platinum, silver, or titanium. The contact pads 130 can be formed of low noble metals such as tin, aluminum, cadmium, galvanized steel, zinc, or magnesium. In the galvanic effect, the low noble metal acts as an anode and the high noble metal acts as a cathode. Ions may move from the anode to the cathode.

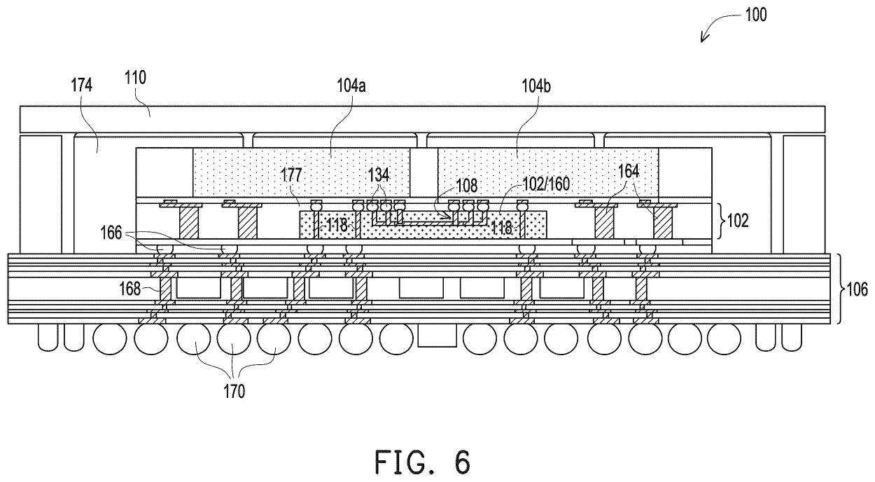

FIG. 6 is a cross-sectional view of an integrated circuit package 100, in accordance with some embodiments. The integrated circuit package 100 of FIG. 6 is one example of an integrated circuit package 100 of FIG. 1B. The integrated circuit package 100 has been assembled after testing for the presence of a galvanic effect at the interposer 102.

The interposer 102 may also be termed an interposer semiconductor chip 160 and corresponds to an example of the interposer 102 shown in FIGS. 1A-5 including the galvanic effect test structure 108. Alternatively, the interposer semiconductor chip 160 may be part of a larger interposer 102. The semiconductor chip 160 may be considered an interposer substructure.

Integrated circuit chips 104a and 104b have been attached to the interposer 102. Solder micro-bumps 134 provide electrical connection between the integrated circuit chips 104a and 104b and the interposer 102/semiconductor chip 160. Internal interconnect structures of the interposer 102/semiconductor chip 160 provide direct electrical communication between the integrated circuit chips 104a and 104b. The galvanic effect test structure 108 is present at the interposer 102/semiconductor chip 160, though not apparent in FIG. 6.

The interposer 102 has been attached to the substrate 106. TSVs 118 electrically connect the integrated circuit chips 104a and 104b to the substrate 106. The interposer 102 also includes reflow structures 164. Solder bumps 166 provide electrical contact to the top surface of the substrate 106. Internal electrical interconnect structures 168 of the substrate 106 connect the solder bumps 166 to solder balls 170 coupled to the bottom of the substrate 106.

A molding compound 174 may cover the interposer 102 and the integrated circuit chips 104a and 104b. An encapsulation 110 may further house the integrated circuit chips 104a and 104b and the interposer 102 and may be positioned on a top surface of the substrate 106. Various other configurations of an integrated circuit package 100 can be utilized without departing from the scope of the present disclosure.

In some embodiments, the top surface of the interposer/semiconductor chip 160 is covered with the passivation layer 177. The passivation layer 177 is a layer of dielectric material. After assembly of the integrated circuit package 100, the passivation layer 177 entirely covers the top surface of the detection contact pad 130b such that the top surface of the detection contact pad 130b can no longer be accessed for electrical coupling. The detection contact pad 130d and the test contact pad 130e of the primary test structure are likewise covered in the passivation layer 177 and can no longer be accessed for electrical coupling.

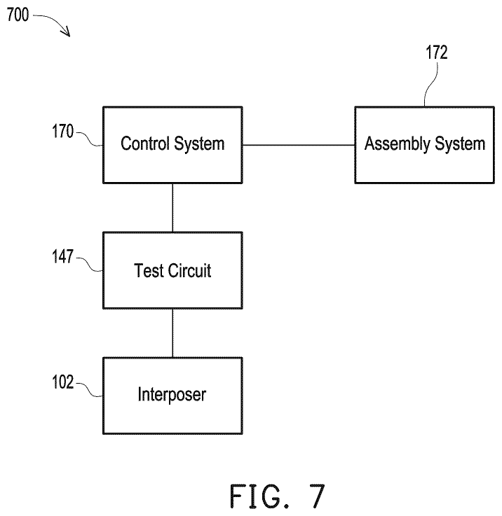

FIG. 7 is a block diagram of a system 700, in accordance with some embodiments. The system 700 includes a control system 170 and the test circuit 147. The control system controls the test circuit 147 to perform one or more tests on an interposer 102 prior to assembling an integrated circuit package with the interposer 102. The interposer 102 includes a galvanic effect test structure 108 (not shown). The control system 170 controls the test circuit 147 to perform a galvanic effect test on the interposer 102. In response to the control system 170, the test circuit 147 applies a test signal to a test contact pad of the galvanic effect test structure. The test circuit 147 receives a response signal via a detection contact pad of the galvanic effect test structure 108.

In some embodiments, the test circuit 147 analyzes the response signal to determine whether there is a flawed the interposer 102. The test circuit 147 can then provide test results data to the control system 170 indicating whether or not the interposer 102 is determined to be defective or suitable for incorporation in an integrated circuit package. If the test results data indicate that the interposer 102 is suitable for incorporation in integrated circuit package, then the control system 170 controls and assembly system 172 to incorporate the interposer 102 and an integrated circuit package. Alternatively, the control system 170 may record a status of the interposer 102 as ready and suitable for assembly. If the test results indicate that the interposer 102 is defective, then the control system 170 may mark or otherwise record a status of the interposer 102 as defective and to be scrapped. The control system 170 may also control the assembly system 172 to not utilize the interposer 102 in integrated circuit package.

In some embodiments, the test circuit 147 provides the response signal to the control system 170. The control system 170 can then analyze the response signal to determine whether or not the interposer 102 is defective.

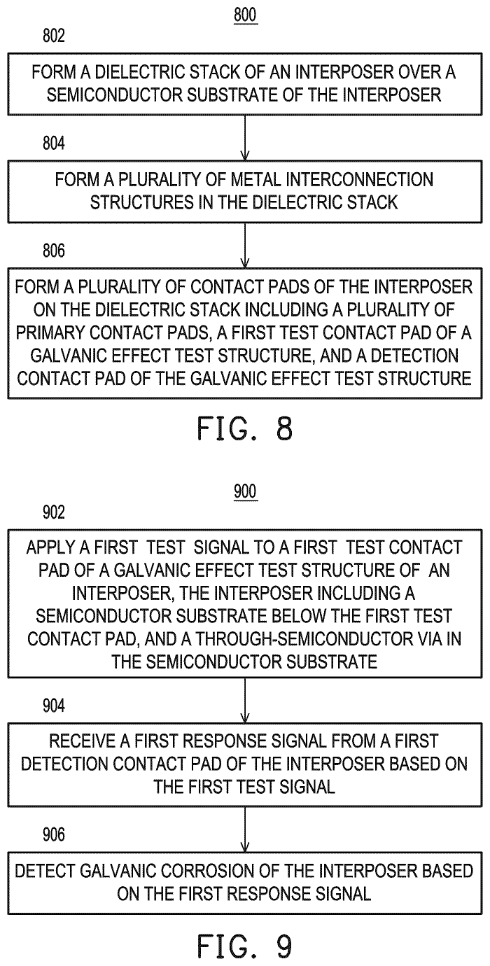

FIG. 8 is a flow diagram of a method 800, in accordance with some embodiments. The method 800 can utilize processes, components, and systems described in relation to FIGS. 1A-7. At 802, the method 800 includes forming a dielectric stack of an interposer over a semiconductor substrate of the interposer. One example of an interposer is the interposer 102 of FIG. 2A. One example of a semiconductor substrate is the semiconductor substrate 112 of FIG. 2A. One example of a dielectric stack is the dielectric stack 114 of FIG. 2A. At 804, the method 800 includes forming a plurality of metal interconnection structures in the dielectric stack. One example of metal interconnection structures are the structures 120, 112, 123, 124, and 126 of FIG. 2A. At 806, the method 800 includes forming a plurality of contact pads of the interposer on the dielectric stack including a plurality of primary contact pads, a first test contact pad of a galvanic effect test structure, and a detection contact pad of the galvanic effect test structure. One example of primary contact pads are the contact pads 130a of FIG. 2A. One example of a test contact pad is the test contact pad 130c of FIG. 2A. One example of a detection contact pad is the detection contact pad 130b of FIG. 2A.

FIG. 9 is a flow diagram of a method 900, in accordance with some embodiments. The method 900 can utilize processes, components, and systems described in relation to FIGS. 1A-7. At 902, the method 900 includes applying a first test signal to a first test contact pad of a galvanic effect test structure of an interposer, the interposer including a semiconductor substrate below the first test contact pad, and a through-semiconductor via in the semiconductor substrate. One example of a galvanic effect test structure is the galvanic effect test structure 108 of FIG. 2A. One example of a test contact pad is the test contact pad 130c of FIG. 2A. One example of an interposer is the interposer 102 of FIG. 2A. One example of a semiconductor substrate is the semiconductor substrate 112 of FIG. 2A. One example of a through semiconductor via is the through semiconductor via 118 of FIG. 2A. At 904, the method 900 includes receiving a first response signal from a first detection contact pad of the interposer based on the first test signal. One example of a detection contact pad is the detection contact pad 130b of FIG. 2A. At 906, the method 900 includes detecting galvanic corrosion of the interposer based on the first response signal.

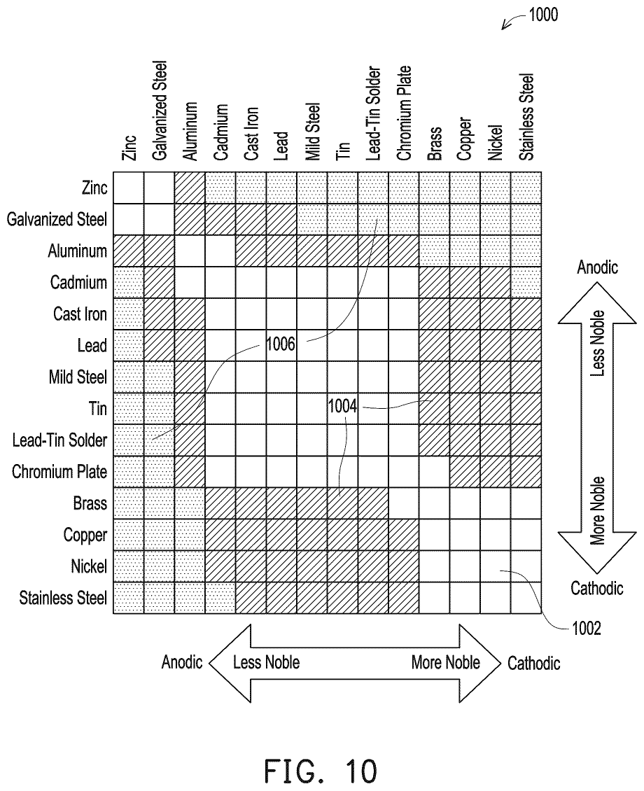

FIG. 10 is a table 1000 illustrating the comparative nobility of metals, in accordance with some embodiments. The table 1000 illustrates regions 1002, 1004, and 1006. The region 1002 indicates metals that are normally compatible of each other and, as such, galvanic corrosion is unlikely to occur. Metals of fall into regions 1004 can potentially have some minor corrosion issues. Metals that fall into the regions 1006 are highly dissimilar and galvanic corrosion will occur under selected circumstances, such as in the presence of an electrolyte. As can be seen, copper and aluminum fall into the region 1006 and the highly dissimilar and prone to galvanic corrosion.

Embodiments of the present disclosure provide an interposer for an integrated circuit package with a galvanic effect test structure. The integrated circuit package includes one or more integrated circuit chips positioned on top of the interposer. The interposer, in turn, is positioned on a substrate. The interposer includes electrical connectors that electrically coupled the one or more integrated circuit chips two electrical connectors on the substrate. Prior to mounting the one or more integrated circuit chips onto the interposer, the interposer undergoes a galvanic effect test utilizing the galvanic effect test structure of the interposer. The galvanic effect test determines whether or not there are defects in the interposer that result in the presence of a galvanic effect. If the testing of the galvanic effect test structure does not indicate the presence of a galvanic effect, then the interposer can be utilized in the integrated circuit package. The one or more integrated circuit chips can be mounted to the interposer and the interposer can be mounted to the substrate.

Embodiments of the present disclosure provide various benefits to integrated circuit packages and integrated circuit packaging techniques. The dedicated galvanic effect test structure enables detection of a galvanic effect on the interposer prior to coupling the one or more chips to the interposer. This avoids the situation in which the galvanic effect is not detected until after the one or more chips are mounted to the interposer, resulting in scrapping of the integrated circuit package and waste of the one or more chips. Instead, if the galvanic effect test structure indicates that the interposer is defective, only the relatively inexpensive interposer is scrapped with no loss of associated integrated circuit chips. This results in higher functioning integrated circuit packages, fewer scrapped wafers, and overall higher yields.

In some embodiments, an integrated circuit package includes a first integrated circuit chip and an interposer coupled to the first integrated chip. The interposer includes a galvanic effect test structure including a test contact pad and a detection contact pad and a plurality of primary contact pads electrically coupled to the first integrated circuit chip. The integrated circuit package includes a substrate coupled to the interposer.

In some embodiments, a method includes forming a dielectric stack of an interposer over a semiconductor substrate of the interposer and forming a plurality of metal interconnection structures in the dielectric stack. The method includes forming a plurality of contact pads of the interposer on the dielectric stack including a plurality of primary contact pads, a first test contact pad of a galvanic effect test structure, and a detection contact pad of the galvanic effect test structure.

In some embodiments, a method includes applying a first test signal to a first test contact pad of a galvanic effect test structure of an interposer. The interposer includes a semiconductor substrate below the first test contact pad, and a through-semiconductor via in the semiconductor substrate. The method includes receiving a first response signal from a first detection contact pad of the interposer based on the first test signal detecting galvanic corrosion of the interposer based on the first response signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package, comprising:
a first integrated circuit chip;
an interposer coupled to the first integrated chip, the interposer including:
a galvanic effect test structure including a test contact pad and a detection contact pad; and
a plurality of primary contact pads electrically coupled to the first integrated circuit chip; and
a substrate coupled to the interposer.

2. The integrated circuit package of claim 1, wherein the galvanic effect test structure includes a buried ground plane electrically coupled to the detection contact pad.

3. The integrated circuit package of claim 2, wherein a surface area of the buried ground plane is at least 4000 times greater than a surface area of the test contact pad.

4. The integrated circuit package of claim 1, wherein the galvanic effect test structure includes:
a metal pillar on the test contact pad; and
a solder bump on the metal pillar.

5. The integrated circuit package of claim 4, wherein an entirety of a top surface of the test contact pad is covered by dielectric material.

6. The integrated circuit package of claim 4, wherein the detection contact pad and the test contact pad are of a low noble metal and the metal pillar is of a high noble metal.

7. The integrated circuit package of claim 6, wherein the low noble metal is aluminum and the high noble metal is copper.

8. The integrated circuit package of claim 1, wherein the detection contact pad surrounds the test contact pad.

9. The integrated circuit package of claim 8, wherein the interposer includes a plurality of primary contact pads surrounding the detection contact pad, wherein one or more of the primary contact pads are electrically coupled to the first integrated circuit chip.

10. The integrated circuit package of claim 9, comprising a second integrated circuit chip attached to the interposer and electrically coupled to one or more of the primary contact pads.

11. The integrated circuit package of claim 1, wherein the interposer includes a semiconductor substrate and a through-semiconductor via in the semiconductor substrate electrically coupling the first integrated circuit chip to the substrate.

12. The integrated circuit package of claim 1, wherein the interposer includes a primary test structure including a second test contact pad and a second detection contact pad.

13. A method, comprising:
forming a dielectric stack of an interposer over a semiconductor substrate of the interposer;
forming a plurality of metal interconnection structures in the dielectric stack; and
forming a plurality of contact pads of the interposer on the dielectric stack including a plurality of primary contact pads, a first test contact pad of a galvanic effect test structure, and a detection contact pad of the galvanic effect test structure.

14. The method of claim 13, comprising forming a ground plane of the galvanic effect test structure in the dielectric stack electrically coupled to the first detection contact pad.

15. The method of claim 14, wherein forming the contact pads includes forming a second test contact pad of a primary test structure and a second detection contact pad of the primary test structure.

16. The method of claim 13, comprising:
performing a galvanic effect test on the interposer by:
applying a test signal to the first test contact pad; and
receiving a response signal from the first detection contact pad; and
determining whether or not galvanic corrosion has occurred at the interposer based on the response signal.

17. A method, comprising:
applying a first test signal to a first test contact pad of a galvanic effect test structure of an interposer, the interposer including a semiconductor substrate below the first test contact pad, and a through-semiconductor via in the semiconductor substrate;
receiving a first response signal from a first detection contact pad of the interposer based on the first test signal; and
detecting galvanic corrosion of the interposer based on the first response signal.

18. The method of claim 17, comprising
applying a second test signal to a second test contact pad of a primary test structure of the interposer; and
receiving a second response signal from a second detection contact pad of the interposer based on the second test signal.

19. The method of claim 17, comprising assembling an integrated circuit package with the interposer, including:
attaching an integrated circuit chip to the interposer and electrically coupling the integrated circuit chip to one or more primary contact pads of the interposer;
attaching the interposer to a substrate; and
encapsulating the interposer and the integrated circuit chip.

20. The method of claim 17, comprising:
scrapping the interposer if galvanic corrosion is present;
if galvanic corrosion is not present, assembling an integrated circuit package with the interposer, including:
attaching an integrated circuit chip to the interposer and electrically coupling the integrated circuit chip to the primary contact pads of the interposer;
attaching the interposer to a substrate; and
encapsulating the interposer and the integrated circuit chip.
